(19) United States
(12) Patent Application Publication
(10) Pub. No.: US 2012/0292267 A1
(43) Pub. Date: Nov. 22, 2012

(54) MOUNTING RAIL WITH INTERNAL POWER CABLE

(75) Inventors: Dror Goldenberg, Zichron Yaakov (IL); Nimer Khazen, Ba'ne Village (IL); Rafi Amarzoyev, Ramat-Yishay (IL)

(73) Assignee: MELLANOX TECHNOLOGIES LTD., Yokneam (IL)

(21) Appl. No.: 13/109,031

(22) Filed: May 17, 2011

(51) Int. Cl. H05K 7/14; H05K 13/00; F16L 3/123

(52) U.S. Cl. 211/26; 248/65; 29/592.1

(57) ABSTRACT

An adapter kit for mounting an electrical apparatus in a rack includes a pair of rails. The rails are configured to be fitted on respective, opposing outer sides of a case of the apparatus and to slide along corresponding tracks on respective inner sides of the rack. At least one of the rails includes a cable channel configured to contain a cable passing through the cable channel between front and rear faces of the case.

### FIELD OF THE INVENTION

The present invention relates generally to cable interconnection in electronics equipment, and particularly to mounting rails with internal cable routing.

### BACKGROUND OF THE INVENTION

In various types of electronics systems, electronics units are mounted in enclosures and connected to power and signal cables. For example, computing and communication installations such as server farms and telecommunication exchanges often comprise a large number of electronics units that are mounted in racks. In these sorts of systems, cable interconnection may have a considerable impact on system aspects such as cost, reliability, scalability and maintainability.

### SUMMARY OF THE INVENTION

An embodiment of the present invention that is described herein provides an adapter kit for mounting an electrical apparatus in a rack. The adapter kit includes a pair of rails, which are configured to be fitted on respective, opposing outer sides of a case of the apparatus and to slide along corresponding tracks on respective inner sides of the rack. At least one of the rails includes a cable channel configured to contain a cable passing through the cable channel between front and rear faces of the case.

In some embodiments, one of the front and rear faces of the case includes an electrical power input of the apparatus, and the cable channel is configured to route a power cable between the power input and the other of the front and rear faces of the case. In a disclosed embodiment, the rails are configured to be fitted on a communication switch. In an embodiment, the adapter kit includes one or more spring fixtures for anchoring the cable in the cable channel. In another embodiment, the rails are configured to interface with standard tracks on the inner sides of the rack. In yet another embodiment, the cable channel is configured to contain a cooling pipe passing through the cable channel between front and rear faces of the case.

There is additionally provided, in accordance with an embodiment of the present invention, apparatus including a case, a cable and a pair of rails for mounting the apparatus in a rack. The rails are fitted on respective, opposing outer sides of the case and are configured to slide along corresponding tracks on respective inner sides of the rack, at least one of the rails including a cable channel configured to contain the cable so as to route the cable through the cable channel between front and rear faces of the case.

There is also provided, in accordance with an embodiment of the present invention, a method for mounting an apparatus in a rack. The method includes fitting on opposing outer sides of a case of the apparatus respective rails that are configured to slide along corresponding tracks on respective inner sides of the rack. A cable is routed between front and rear faces of the case through a cable channel that is included in at least one of the rails.

The present invention will be more fully understood from the following detailed description of the embodiments thereof, taken together with the drawings in which:

### BRIEF DESCRIPTION OF THE DRAWINGS

FIG. 1 is a three-dimensional exploded view of a communication switch mounted in a rack, in accordance with an embodiment of the present invention;

FIG. 2 is a three-dimensional exploded view showing installation of a power cable in a mounting rail, in accordance with an embodiment of the present invention;

FIG. 3 is a side view of a power cable routed through a mounting rail, in accordance with an embodiment of the present invention;

FIGS. 4A and 4B are respective top and side views of a mounting rail, in accordance with an embodiment of the present invention; and

FIG. 5 is a three-dimensional view of a communication switch mounted in a rack, in accordance with an embodiment of the present invention.

### DETAILED DESCRIPTION OF EMBODIMENTS

### Overview

Embodiments of the present invention that are described hereinbelow provide improved methods and devices for routing cables in electrical equipment that is mounted in a rack. Although the embodiments described herein refer mainly to routing of electrical power cables in Top-Of-Rack (TOR) switches, the disclosed techniques can be used for routing other sorts of cables and/or in other kinds of electrical equipment.

In some embodiments, a pair of mounting rails is fitted on opposite outer sides of a case of an electrical apparatus. The rails are configured to slide along corresponding tracks that are fitted on respective inner sides of the rack. Using this rail mechanism, the apparatus can be inserted and extracted into and out of the rack. At least one of the rails comprises a cable channel for passing a cable between front and rear faces of the case.

In one embodiment, the cable carries electrical power between the front and back of the rack, e.g., from the front of the rack to a power supply connector on the rear face of the apparatus case. Passing a power cable through the mounting rail enables supplying electrical power to the apparatus from the front of the rack, even when the power supply connector of the apparatus is located on the back face of the case.

Such a scheme is advantageous because the front of the rack is easily accessible for maintenance, whereas the rear of the rack is sometimes difficult to access. It is common in electrical apparatus, however, that the power connection and power supply are located at the rear of the apparatus, so as to leave the front panel free for communication cabling and user controls. The disclosed rail configuration enables the power cable to be connected at the front side of the rack and permits the rack to be populated with equipment at high density, because the power cable is routed through the rail at the side of the apparatus, without requiring any vertical space above or below the apparatus.

The power cable is typically fixed to the rail and travels with the apparatus as it slides in and out of the rack. As a result, the back of the rack is free of hanging cables that may be damaged or entangled. In some embodiments, the disclosed rail configuration is implemented in an installation kit that comprises a pair of rails. Such a kit may be used with standard mounting tracks on the rack side.

### System Description

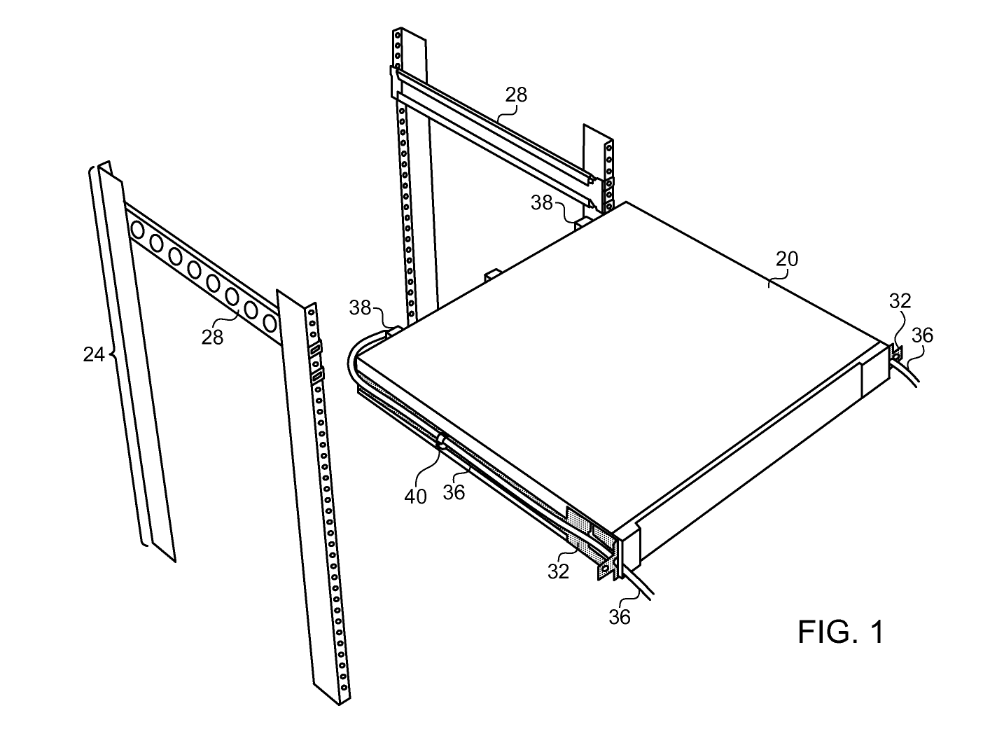

FIG. 1 is a three-dimensional exploded view of a communication switch 20 mounted in a rack 24, in accordance with an embodiment of the present invention. In the present example, switch 20 comprises a Top-Of-Rack (TOR) switch. In alternative embodiments, however, switch 20 may comprise any other suitable type of switch. Although the description that follows refers to switches, the disclosed schemes can be used for mounting and cabling of any other suitable electrical apparatus fitted in a rack.

Rack 24 may comprise, for example, a standard 19″ rack or any other suitable rack type. For the sake of conceptual clarity, only a skeleton frame of the rack is shown in the figure. Other elements of the rack, and other equipment that may be mounted in the rack, are omitted from the figure for the sake of clarity.

The interior of rack 24 comprises a pair of tracks 28 for mounting switch 20. A pair of mounting rails 32 is fitted on opposite outer sides of the case of switch 20. When switch 20 is mounted in rack 24, each rail 32 is configured to slide along the corresponding track 28. Using this mechanism, an operator (e.g., technician or administrator) can slide switch 20 into and out of the rack, for example for maintenance or replacement purposes. The front face of switch 20 may comprise switch ports, indicator lights and/or any other element used for operating the switch.

In some embodiments, at least one of rails 32 comprises a cable channel for routing a cable 36 between the front and rear faces of switch 20. In the present example, both rails 32 comprise such a cable channel so that two cables 36 can be routed via the rails between the front and back of the switch. In alternative embodiments, only one of the rails comprises a cable channel.

In the present embodiment, cable 36 comprises an Alternative Current (AC) power cable that is used for providing electrical power to switch 20. In alternative embodiments, the cable channel can be used for routing any other suitable type of cable, such as Direct Current (DC) power cables or signal cables, between the front and rear of the switch. Each cable channel can be used for routing a single cable or multiple cables.

In the embodiment of FIG. 1, an AC power source (not shown in the figure) is available at the front of rack 24. The power supply of switch 20, however, is located at the rear of the switch, i.e., toward the rear of the rack. Cable 36 connects the power source at the front of the rack, through rail 36, to a power connector 38 that plugs into the power supply at the rear of switch 20.

A configuration of this sort enables the entire operation and maintenance of the switch to be performed from the front of the rack, which is usually easy to access. There is typically no need to access the rear of the rack, which is often difficult to access. Routing cable 36 through rail 32 utilizes the available separation between switch 20 and rack 24 for passing cable 36, and therefore incurs little or no additional space.

As can be seen in the figure, cable 36 is fixed to switch 20 and travels together with the switch as it slides along tracks 28. Thus, there are no loose or hanging cables at the rear of rack 24.

The additional width needed for passing the cable through rail 32 (corresponding to the depth of the cable channel) typically depends on the cable diameter. In an example embodiment, a standard 19″ rack has an internal available width of 450 mm. Out of this width, 22 mm are reserved for the pair of rails 36. Thus, TOR switch 20 has a maximum width of 428 mm.

In an example embodiment, the total thickness of each rail 32 is approximately 8.7 mm, such that the depth of the cable channel is on the order of 7 mm. The total width of the rail in this embodiment is on the order of 23 mm. Rails 32 (and possibly the corresponding tracks 28) can be produced at various lengths, to match various possible depths of switch 20 or other electrical units. Possible lengths are, for example, on the order of 400 mm or 600 mm. Note that the sizes specified in the paragraphs above are given purely by way of example, and any other suitable sizes can be used in alternative embodiments.

In some embodiments, one or more spring fixtures 40 (e.g., two spring fixtures per rail) hold cable 36 in place within the cable channel of rail 32. The structure of rail 32 is shown in greater detail in subsequent figures.

### Rail Kit and Installation Details

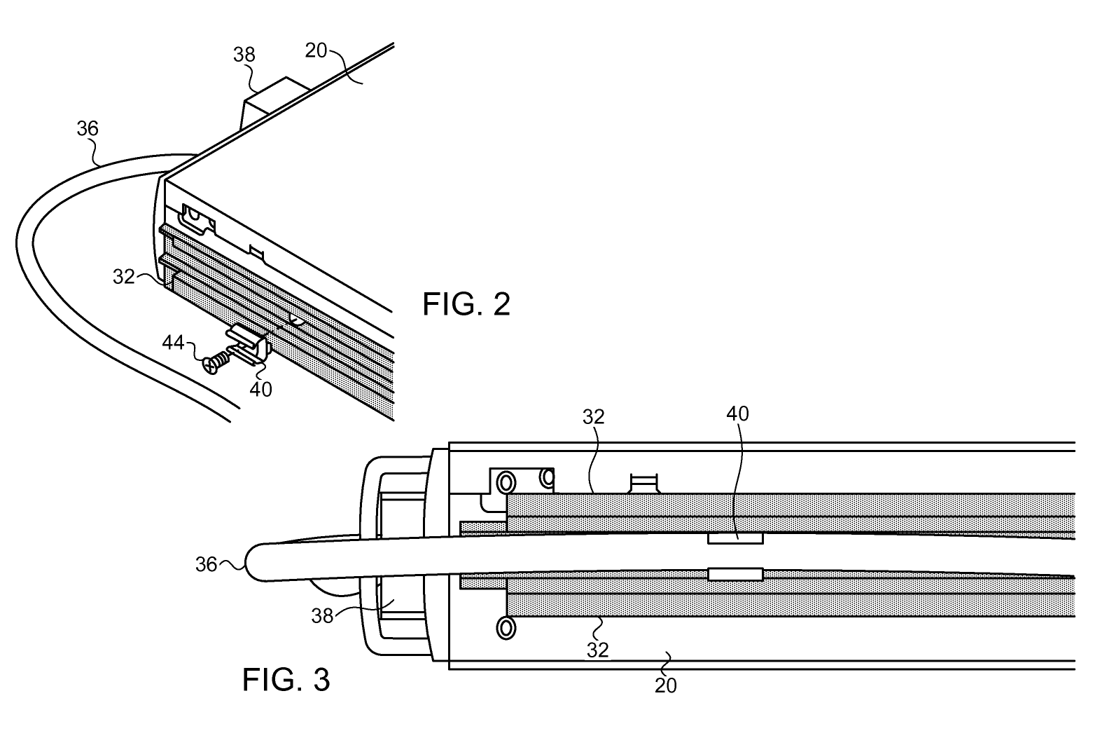

FIG. 2 is a three-dimensional exploded view showing installation of cable 36 in rail 32, in accordance with an embodiment of the present invention. In this exploded view the cable is shown outside the cable channel, in order to provide clear visibility of the various system elements. The figure shows cable 36 connected to the rear face of switch 20 using connector 38. Rail 32 is connected to one the sides of the case of switch 20. Spring fixture 40, which is fixed by a screw 44, is used for anchoring cable 36 is the cable channel of rail 32. The same screw may also be used as one of the screws that connect rail 32 to switch 20.

FIG. 3 is a side view of cable 36 routed through rail 36, in accordance with an embodiment of the present invention. This view shows the cable as it is routed through the cable channel of rail 32. Spring fixture 40 is shown holding the cable in place.

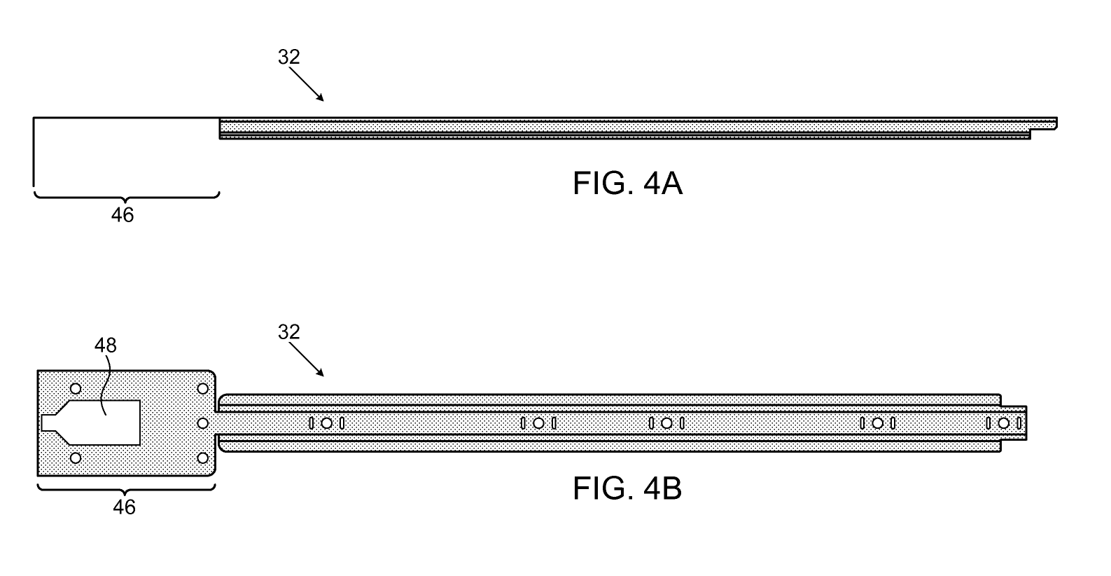

FIGS. 4A and 4B are respective top and side views of rail 32, in accordance with an embodiment of the present invention. The left-hand-side section (denoted 46) of the rail connects to the front end of the side of switch 20 (see FIG. 1). This section comprises an opening 48 for inserting connector 38 during installation. The depth of the cable channel (the thickness of the rail—11 mm in the above example) can be seen in FIG. 4A.

Rail 32 can be fabricated from any suitable material and using any suitable manufacturing process. In an example embodiment, rail 32 is fabricated from a single piece of sheet aluminum that is cut and bent into the desired shape.

In a typical installation procedure, connector 38 is inserted through opening 48 of rail 32. The rail is then screwed to the side of switch 20. Connector 38 is then plugged into the switch. Then, cable 36 is routed through the cable channel of rail 32 and held in place by spring fixture 40. In alternative embodiments, any other suitable installation sequence can be used.

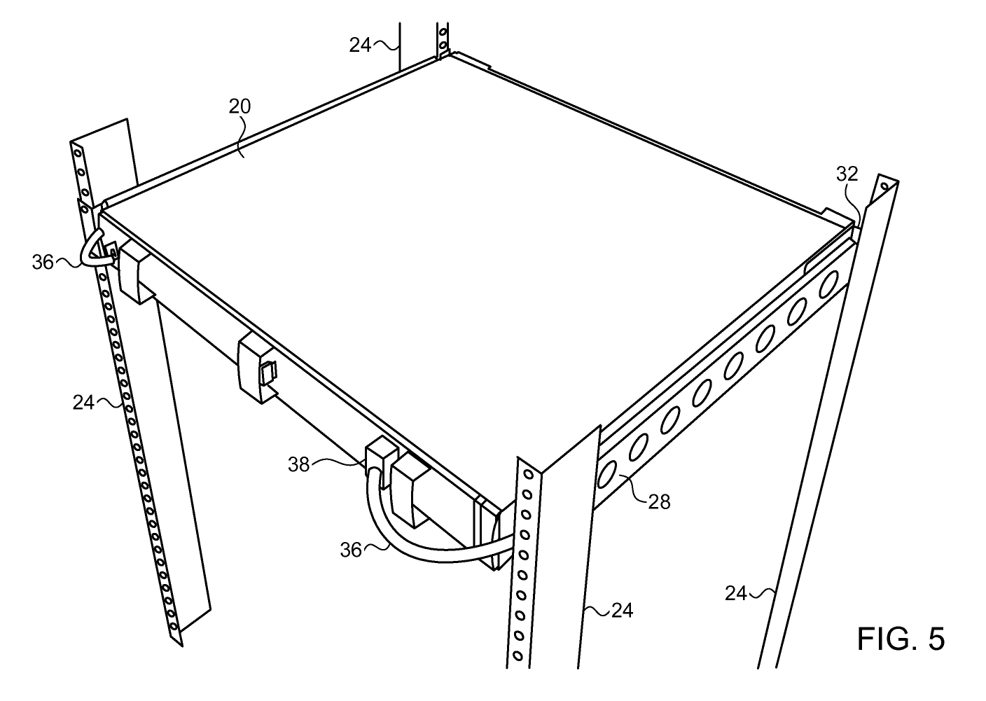

FIG. 5 is a three-dimensional view of switch 20 mounted in rack 24, in accordance with an embodiment of the present invention. The present view is shown from the rear of the rack when the switch is fully inserted on tracks 28.

The mechanical configurations of tracks 28, rails 32, cable 36 and other mounting and cabling elements described above are example configurations, which are shown purely by way of example. In alternative embodiments, any other suitable configuration can also be used.

In some embodiments, rails 32 are provided as a kit. Such a kit typically comprises a pair of rails 32 and possibly the associated spring fixtures, screws or other installation accessories. Note that such a kit may be used with standard mounting tracks on the rack side. Thus, legacy racks do not require modification in order to fit the disclosed rails having internal cable routing.

Although the embodiments described herein mainly address mounting and cabling of electrical equipment in racks, the methods and systems described herein can also be used in various other applications. As noted above, the disclosed techniques can be used for routing cables other than power cables, such as signal or control lines. Further alternatively, the disclosed techniques can be used for routing cooling pipes, e.g., pipes carrying water, air or any other suitable cooling material.

It will thus be appreciated that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. An adapter kit for mounting an electrical apparatus in a rack, the kit comprising a pair of rails configured to be fitted on respective, opposing outer sides of a case of the apparatus and to slide along corresponding tracks on respective inner sides of the rack, at least one of the rails comprising a cable channel configured to contain a cable passing through the cable channel between front and rear faces of the case.

2. The adapter kit according to claim 1, wherein one of the front and rear faces of the case comprises an electrical power input of the apparatus, and wherein the cable channel is configured to route a power cable between the power input and the other of the front and rear faces of the case.

3. The adapter kit according to claim 1, wherein the rails are configured to be fitted on a communication switch.

4. The adapter kit according to claim 1, and comprising one or more spring fixtures for anchoring the cable in the cable channel.

5. The adapter kit according to claim 1, wherein the rails are configured to interface with standard tracks on the inner sides of the rack.

6. The adapter kit according to claim 1, wherein the cable channel is configured to contain a cooling pipe passing through the cable channel between front and rear faces of the case.

7. Apparatus, comprising:
a case;
a cable; and
a pair of rails for mounting the apparatus in a rack, the rails fitted on respective, opposing outer sides of the case and are configured to slide along corresponding tracks on respective inner sides of the rack, at least one of the rails comprising a cable channel configured to contain the cable so as to route the cable through the cable channel between front and rear faces of the case.

8. The apparatus according to claim 7, wherein one of the front and rear faces of the case comprises an electrical power input of the apparatus, and wherein the cable comprises a power cable that carries electrical power between the electrical power input and the other of the front and rear faces of the case.

9. The apparatus according to claim 7, wherein the case contains a communication switch.

10. The apparatus according to claim 7, and comprising one or more spring fixtures for anchoring the cable in the cable channel.

11. The apparatus according to claim 7, wherein the rails are configured to interface with standard tracks on the inner sides of the rack.

12. The apparatus according to claim 7, wherein the cable channel is configured to contain a cooling pipe passing through the cable channel between front and rear faces of the case.

13. A method for mounting an apparatus in a rack, comprising:
fitting on opposing outer sides of a case of the apparatus respective rails that are configured to slide along corresponding tracks on respective inner sides of the rack; and
routing a cable between front and rear faces of the case through a cable channel that is comprised in at least one of the rails.
